(19) United States
(12) Patent Application Publication
(10) Pub. No.: US 2005/0129977 A1
(43) Pub. Date: Jun. 16, 2005

(54) Method and apparatus for forming patterned coated films

(75) Inventors: Hak Fei Poon, Niskayuna, NY (US); Dennis Joseph Coyle, Clifton Park, NY (US); Svetlana Rogojevic, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 10/735,503

(22) Filed: Dec. 12, 2003

(51) Int. Cl. H05B 33/12; H05B 33/10

(52) U.S. Cl. 428/690; 428/917; 428/201; 313/504; 313/506; 427/66; 427/270

(57) ABSTRACT

An electro-luminescent device such as a photovoltaic cell or an OLED. The electro-luminescent device comprises at least one electrode and an electro-luminescent layer disposed on the electrode. The electro-luminescent layer comprises an electro-luminescent polymeric material and has a first pattern disposed on a surface adjacent to the electrode. The electro-luminescent layer has a substantially uniform thickness. An apparatus and method of uniformly patterning such electro-luminescent layer or layers by solvating and wiping in a tangential direction are also disclosed.

### BACKGROUND OF INVENTION

This invention relates to an electro-luminescent device, such as an organic light emitting diode. More particularly, the invention relates to a method of uniformly patterning an electro-luminescent layer of such electro-luminescent devices.

Electro-active devices, such as organic light emitting diodes (referred hereinafter to as “OLEDs”), are widely used in organic transistors, fuel cell components, microelectronics processing, microanalytical test procedures, and in specialty electronics. One of the features of such devices is an electro-luminescent layer, formed from photo-sensitive materials, that emits light on receiving an electrical impulse. In order to facilitate miniaturization, conform to device geometry, and maximize electro-luminescent yield, the electro-luminescent layer must often be patterned to various textures, topography, and geometries.

Electro-luminescent layer patterning has been conventionally performed using stamping or laser ablation. In stamping, a pattern is imprinted upon the layer using mechanical force upon a patterned die or a stamping head, whereas in laser ablation, a patterned photomask covers the area to be patterned while the remaining area is selectively etched using a laser beam.

One problem associated with such patterning of electro-luminescent layers is that stamping leaves behind a substantial amount of material residue on the layer surface. Patterning by stamping also does not guarantee uniform, reproducible, and precise patterning over large specimens. While laser ablation may yield uniform, reproducible, and precisely patterned surfaces, the process needs high vacuum conditions, produces excessive debris around the patterned area, is expensive, and cannot be performed on large specimens or in fieldwork.

The current methods for patterning an electro-luminescent layer in electro-active devices use mechanical or laser-beam techniques that do not enable patterned surfaces to be patterned to precision in minimal turnaround times. Therefore, what is needed is an electro-active device having an electro-luminescent layer that is precisely and quickly patterned to uniform thickness. What is also needed is a method for patterning such an electro-luminescent layer that is applicable to a variety of material compositions with a variety of solvating species. What is also needed is a patterning method that is effectively independent of the processing or forming history of the electro-luminescent film.

### BRIEF SUMMARY OF THE INVENTION

The present invention meets these and other needs by providing a patterned electro-luminescent layer of substantially uniform thickness and a method of forming such a patterned electro-luminescent layer on a substrate. Different kinds of electro-luminescent layers can be patterned by this method. An electro-luminescent device, such as a photovoltaic cell or OLED, having at least such one electro-luminescent layer, is also provided. The invention also includes an apparatus for making an electro-luminescent layer by selectively removing at least one coating from a surface of a substrate.

Accordingly, one aspect of the invention is to provide an electro-luminescent device. The electro-luminescent device comprises at least one electrode and an electro-luminescent layer disposed on the at least one electrode. The electro-luminescent layer comprises an electro-luminescent polymeric material and has a first pattern disposed on a surface adjacent to the at least one electrode and has a substantially uniform thickness.

A second aspect of the invention is to provide an electro-luminescent layer for an electro-luminescent device. The electro-luminescent layer comprises an electro-luminescent polymeric material. The electro-luminescent layer is patterned and has a substantially uniform thickness, and is formed by forming a continuous sheet of electro-luminescent polymeric material and removing a portion of the continuous sheet by wiping a surface of the continuous sheet in a direction that is tangential to the surface.

A third aspect of the invention is to provide an electro-luminescent device. The electro-luminescent device comprises at least one electrode; an electro-luminescent layer; and at least one conductive layer disposed between the at least one electrode and the electro-luminescent layer. The electro-luminescent layer comprises an electro-luminescent polymeric material, is patterned, and has a substantially uniform thickness. The electro-luminescent layer is formed by forming a continuous sheet of electro-luminescent polymeric material and removing a portion of the continuous sheet by wiping a surface of the continuous sheet in a direction that is tangential to the surface.

A fourth aspect of the invention is to provide a light source comprising a plurality of electro-luminescent devices. Each electro-luminescent device comprises at least one electrode; an electro-luminescent layer, and at least one conductive layer disposed between the at least one electrode and the electro-luminescent layer. The electro-luminescent layer comprises an electro-luminescent polymeric material, and is patterned and has a substantially uniform thickness. The electro-luminescent layer is formed by forming a continuous sheet of electro-luminescent polymeric material and removing a portion of the continuous sheet by wiping a surface of the continuous sheet in a direction that is tangential to the surface.

A fifth aspect of the invention is to provide a method of selectively removing at least one coating from a surface of a substrate. The method comprises the steps of: providing a substrate having the coating disposed on the surface; tangentially contacting a portion of the coating with a wiping head; and wiping the portion with the wiping head to remove a portion of the coating from the substrate.

A sixth aspect of the invention is to provide an apparatus for selectively removing at least one coating from a surface of a substrate. The apparatus comprises: a means for supplying the substrate having the at least one coating; a wiping head for removing a portion of the coating, wherein the wiping head tangentially contacts the coating; and a means for collecting the substrate after removing the portion.

A seventh aspect of the invention is to provide a wiping head for removing a portion of at least one coating disposed on a surface of a substrate. The wiping head comprises a contact surface for contacting and removing the portion of the coating. The contact surface tangentially contacts the portion and has a predetermined geometry.

These and other aspects, advantages, and salient features of the present invention will become apparent from the following detailed description, the accompanying drawings, and the appended claims.

### BRIEF DESCRIPTION OF THE DRAWINGS

FIG. 1 is a schematic view of a light source comprising a plurality of electro-luminescent devices on an optical panel;

FIG. 2 is a cross-sectional view of an electro-luminescent device;

FIG. 3 is a schematic view of one embodiment of an electro-luminescent device with its constituent patterns;

FIG. 4 is a schematic view of a second embodiment of a patterned electro-luminescent device having a coated portion and uncoated portion;

FIG. 5 is a schematic view of an embodiment for removing a portion of continuous sheet by wiping;

FIG. 6 is a schematic cross-sectional view of the contact surface of a wiping head of the present invention;

FIG. 7A is a schematic view of a method of selectively removing at least one coating from a surface of a substrate; and

FIG. 7B is a second schematic view of a method of selectively removing at least one coating from a surface of a substrate.

### DETAILED DESCRIPTION OF THE INVENTION

In the following description, like reference characters designate like or corresponding parts throughout the several views shown in the figures. It is also understood that terms such as “top”, “bottom”, “outward”, “inward”, and the like are words of convenience and are not to be construed as limiting terms.

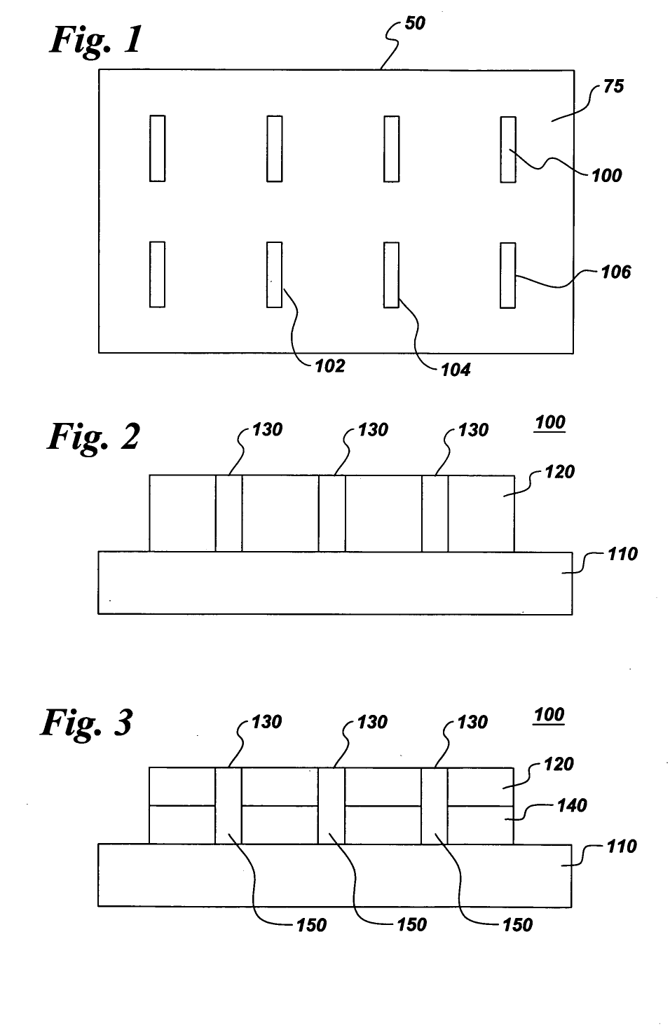

Referring to the drawings in general and to FIG. 1 in particular, it will be understood that the illustrations are for the purpose of describing a preferred embodiment of the invention and are not intended to limit the invention thereto.

Visible light sources produce light in different ways. Such devices may comprise different components and mechanisms for producing light and some sources may produce light more efficiently than others. Many light sources are made of electro-luminescent materials arranged as coatings or films upon an electro-active substrate (often called an electrode). Consequently, the film may be patterned or textured to suit design requirements.

Common methods of film patterning, such as ink jet printing, deposit the coating one drop at a time, by creating polyimide wells to position the drop on the film surface. This method is commonly used in pixels for displays. Films may also be patterned or textured using methods such as, but not limited to, screen printing, gravure printing, flexographic printing, offset lithographic printing, spin coating, spray coating, meniscus coating, and dip coating. However, it is difficult to dispose and pattern coating layers of uniform thickness using such methods with subsequent solvent deposition in which the solvent creates a crater or channel upon drying. One embodiment of the present invention discloses a patterning method applicable to large area devices with coatings of uniform thickness. A common approach to producing patterned electro-luminescent film is to selectively remove portions of the electro-luminescent coating from a continuous film of the electro-luminescent material. This is conventionally done using laser ablation, plasma etching, scratching the film surface, tape lifting, and lifting off under high temperature or pressure using a die or stamp. However, there are certain disadvantages associated with each of these methods. For instance, laser ablation and plasma etching focus on small working areas of the specimen, and the cost for scaling up the process can be very high. Scratching requires plowing through the continuous coating with a stiff stylus, which can potentially damage the underlying layers or substrates. Stamping and lifting with a rubbery die offer an affordable but qualitatively unacceptable solution. The liftoff process can be uniquely related to the materials of construction of the die and may result in incomplete coating removal with residues deposited on the stamped area. The residues can also affect the final properties and performance of the electro-luminescent device.

The present invention provides a process to selectively remove a portion of a continuous electro-luminescent film and to produce a sharply patterned electro-luminescent film.

The invention also provides a process to remove coating material from a continuous electro-luminescent film via wiping with a ‘moistened’ soft head. In another embodiment, the wiping head contains solvents that solvate (or moisten, using aqueous or non-aqueous solvents) the electro-luminescent film. A tangential wiping action using the wiping head assists in removing the solvated area.

In another embodiment, the invention also provides a solvent system that enables removal of portions of multiple layers of film in a single step. The multiple layers may either be identical or distinct from each other.

In one embodiment of the present invention, shown in FIG. 1, a light source 50 comprises several different electro-luminescent devices 100, 102, 104, and 106 mounted on an optical panel 75. The electro-luminescent devices may differ from each other in geometry, processing, spatial assembly, and function. A cross-sectional view of one such electro-luminescent device 100 is schematically shown in FIG. 2. Electro-luminescent device 100 includes electrode 110 and an electro-luminescent layer 120 disposed thereon. The electro-luminescent layer 120 has a first pattern 130 disposed on a surface adjacent to electrode 110. Electro-luminescent layer 120 is made from an electro-luminescent polymeric material and has a substantially uniform thickness. In another embodiment, shown in FIG. 3, the electro-luminescent device 100 further comprises a conductive layer 140 disposed between the electrode 110 and the electro-luminescent layer 120. The conductive layer 140 has a second pattern 150 disposed on a surface adjacent to electro-luminescent layer 120. In yet another embodiment, the first pattern 130 is identical to the second pattern 150. Conductive layer 140 comprises at least one of poly (3,4-ethylenedioxythiophene) (also referred to hereinafter as “PEDOT”), poly (3,4-propylenedioxythiophene) (also referred to hereinafter as “PProDOT”), polystyrenesulfonate (PSS), polyvinylcarbazole (also referred to hereinafter as “PVK”), combinations thereof, and the like. Electrode 110 comprises at least one of a metal, indium tin oxide, silicon, and combinations thereof.

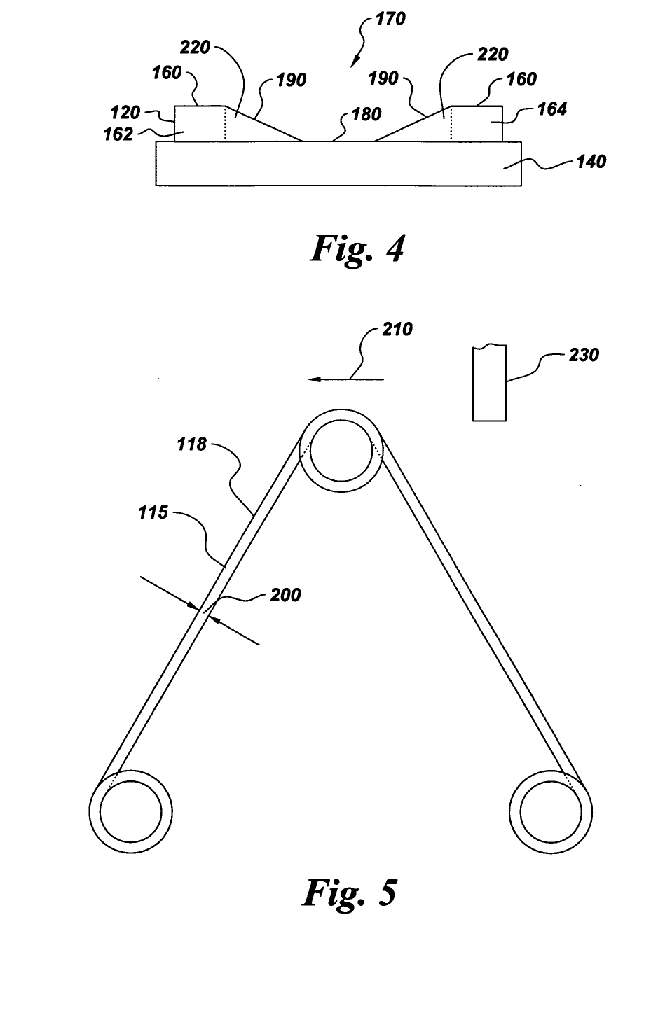

In the embodiment shown in FIG. 4, electro-luminescent layer 120 is disposed on one of conductive layer 140 and comprises a first pattern 130. First pattern 130 comprises at least one coated portion 160 having a coated surface area and at least one uncoated portion 170 having an uncoated surface area, wherein the at least one uncoated portion 170 intersects the coated portion 160 to form a first coated area 162 and a second coated area 164. Coated surface area 160 is frequently greater than the uncoated surface area 170. Additionally, the uncoated portion 170 comprises at least one channel 180 that cuts through coated portion 160 such that the channel 180 has a plurality of walls 190. Each of the plurality of walls 190 has a boundary width 220 of less than 20% of the width of channel 180. Coated portion 160 has a thickness in a range from about 50 nm to about 150 nm.

The electro-luminescent layer 120 comprises a polymeric material such as, but not limited to, conjugated polymers, such as polyfluorenes, polyphenylenes (PPPs), and poly para-(phenylenevinylenes) (PPVs). The conductive layer 140 comprises at least one of poly (3,4-ethylenedioxythiophene) (commonly known as “PEDOT”), poly (3,4-propylenedioxythiophene) (also referred to herein as “PProDOT”), polystyrenesulfonate (also referred to herein as “PSS”), polyvinylcarbazole (also referred to herein as “PVK”), and combinations thereof. In other embodiments of the invention, electro-luminescent device 100 further comprises at least one additional polymer layer that performs conductive, emissive, charge injection, and charge blocking functions in the electro-luminescent device 100. Electrode 110 comprises a high work function material capable of forming ohmic contact with the upper adjacent layer (conductive layer 140). Electrode 110 comprises at least one of: indium tin oxide; tin oxide; zinc oxide; fluorinated zinc oxide; tin doped zinc oxide; cadmium tin oxide; gold; a conductive polymer comprising at least one of PEDOT, PProDOT, PSS, PVK; and combinations thereof. In other embodiments of the invention, electrode 110 is supported by a substrate material such as, but not limited to, a polycarbonate, a polyolefin, a polyester, a polyimide, a polysulfone, an acrylate, glass, metal foil, and combinations thereof.

In another embodiment of the present invention, an electro-luminescent layer 120 is disclosed for an electro-luminescent device 100. The electro-luminescent layer 120 comprises an electro-luminescent polymeric material. The electro-luminescent layer 120 is patterned and has a substantially uniform thickness 200, and is formed by forming a continuous layer 115 of the electro-luminescent polymeric material and removing a portion of the continuous layer 115 by wiping a surface 118 of the continuous layer 115 in a direction that is tangential 210 to the surface, as shown in FIG. 5.

Electro-luminescent layer 120 is disposed adjacent to at least one conductive layer 140. Electro-luminescent layer 120 possesses a pattern 130 comprising at least one coated portion 160 having a coated surface area and at least one uncoated portion 170 having an uncoated surface area, wherein the at least one uncoated portion intersects the coated portion to form a first coated area 162 and a second coated area 164. Typically, the coated surface area is greater than the uncoated surface area. Additionally, the uncoated portion 170 comprises at least one channel 180 that cuts through coated portion 160 such that channel 180 has a plurality of walls 190 each of the plurality of walls 190 has a boundary width 220 of less than 20% of the width of channel 180. Coated surface area 160 has a thickness in a range from about 50 nm to about 150 nm.

In one embodiment, electro-luminescent layer 120 is made from a continuous polymer sheet 115. The continuous polymer sheet 115 is formed by depositing a polymeric film, such as PEDOT or the like, on a continuous sheet of a substrate, patterning the polymeric film, and baking the polymeric film at a temperature between about 50° C. and about 200° C. The actual baking temperature depends upon the polymer substrate that is used to support the continuous polymer sheet 115. The polymeric film is then coated with an electro-luminescent material to form electro-luminescent layer 120 on the polymer film, and the electro-luminescent layer 120 is then patterned. The steps of patterning the polymeric film, patterning electro-luminescent layer 120, and baking may be performed in any sequential order. For example, application of polymeric and electro-luminescent films, patterning, and baking may proceed according to any of the sequences shown in Table 1.

TABLE 1
Different, non-limiting embodiments of the present invention showing
various process methods in PEDOT film application and patterning. In the table,
“EL” refers to the application of electro-luminescent film.

| Sl. | Step 1 | Step 2 | Step 3 | Step 4 | Step 5 | Step 6 | Step 7 |
|---|---|---|---|---|---|---|---|
| 1. | apply PEDOT | pattern | dry | bake | apply EL | pattern EL | dry |
| | | PEDOT | | | | | |
| 2. | apply | pattern | dry | bake | apply EL | dry | pattern EL |
| | PEDOT | PEDOT | | | | | |
| 3. | apply | dry | pattern | bake | apply EL | pattern EL | dry |
| | PEDOT | | PEDOT | | | | |
| 4. | apply | dry | pattern | bake | apply EL | dry | pattern EL |
| | PEDOT | | PEDOT | | | | |
| 5. | apply | dry | bake | pattern | apply EL | pattern EL | dry |
| | PEDOT | | | PEDOT | | | |
| 6. | apply | dry | bake | pattern | apply EL | dry | pattern EL |
| | PEDOT | | | PEDOT | | | |
| 7. | apply | dry | bake | apply | pattern EL | dry | pattern |
| | PEDOT | | | EL | | | PEDOT |
| 8. | apply | dry | bake | apply | dry | pattern EL | pattern |
| | PEDOT | | | EL | | | PEDOT |
| 9. | apply | dry | bake | apply | dry | pattern EL and | |
| | PEDOT | | | EL | | PEDOT | |
| | | | | | | simultaneously | |
| 10. | apply | dry | apply | pattern | dry | pattern | bake |
| | PEDOT | | EL | EL | | PEDOT | |
| 11. | apply | dry | apply | dry | pattern EL | pattern | bake |
| | PEDOT | | EL | | | PEDOT | |
| 12. | apply | dry | apply | dry | pattern EL and | | bake |
| | PEDOT | | EL | | PEDOT | | |
| | | | | | simultaneously | | |
| 13. | apply | dry | apply | pattern | dry | bake | pattern |
| | PEDOT | | EL | EL | | | PEDOT |
| 14. | apply | dry | apply | dry | bake | pattern EL | pattern |
| | PEDOT | | EL | | | | PEDOT |

| | | | | | | |
|---|---|---|---|---|---|---|
| 15. | apply | dry | apply | dry | bake | pattern EL and |
| | PEDOT | | EL | | | PEDOT |
| | | | | | | simultaneously |

To facilitate film removal over a selected area of the electro-luminescent film, a portion of the continuous polymer sheet 115 is solvated by at least one of water, methanol, ethanol, isopropanol, acetone, toluene, xylene, and combinations thereof. The surface of the solvated portion of continuous polymer sheet 115 is wiped by wiping head 230 remove a portion of at least one film, thereby patterning the film, or films. Wiping head 230 comprises at least one of a sponge, elastomer, thermoplastic, thermoset, fiber mat, porous material, polyurethane rubber, synthetic rubber, natural rubber, silicones, polydimethylsiloxane (PDMS), textured materials, and combinations thereof.

In one embodiment of the invention, the solvating species are selected for removing a single layer of film with each wiping action without damaging underlying layers. In another embodiment, the solvating species are selected to facilitate removal of multiple layers with each wiping. For example, an electro-luminescent film in a two-layer structure can be patterned using xylene as a solvent without damaging a PEDOT layer underneath. In yet another embodiment, two polymer layers can also be removed in one step with a solvent system containing water and xylene. In this particular embodiment, isopropanol is used to facilitate mixing of water and xylene to yield a homogeneous solution.

In another embodiment of the claimed invention, a method of selectively removing at least one coating from a surface of a substrate is disclosed and generally shown in FIGS. 7A and 7B. The method comprises the steps of: providing substrate 410 having at least one coating 420 disposed on a surface of the substrate 410; tangentially contacting a portion 460 of coating 420 with wiping head 230; and wiping the portion 460 with wiping head 230 in a direction 210 that is tangential to the surface to remove a portion of coating 420 from substrate 410. Coating 420 may be either a wet coating or a dry coating. Alternatively, coating 420 may include both wet and dry regions. In one embodiment, coating 420 is baked onto the surface of substrate 410. Wiping head 230 is at least one of a dry wiping head and a wiping head moistened with solvent 250. Solvent 250 comprises at least one of a polar solvent, a nonpolar solvent, and combinations thereof. Non-limiting examples of solvent 250 include water, methanol, ethanol, isopropanol, acetone, toluene, xylene, and combinations thereof. The choice of solvent 250 depends entirely on the coating to be removed. In one embodiment, wiping head 230 is moistened by injecting solvent 250 into the head 230 while wiping head 230 wipes portion 460 of coating 120. In another embodiment, wiping head 230 is moistened prior to wiping by at least one of dipping wiping head 230 into a bath containing solvent 250, soaking wiping head 230 in a bath containing solvent 250, spraying either wiping head 230 or portion 460 with solvent 250, or the like.

Solvent 250 may be either polar or non-polar. For each polymer coating material, there are usually three solubility parameters that account for the non-polar, polar, and hydrogen bonding strength of the polymer. Similarly, there are three corresponding solubility parameters for each solvent. The best solvent for a polymer is one having solubility parameters that match those of the polymer.

### EXAMPLE 1

### Removal of Coating Comprising of Polymers Having Extreme Solubility Characteristics (i.e. Co-Existence of Both Very Polar and Non-Polar Materials)

In typical instances, the electro-luminescent layer comprises both (i) a conductive polymer coating, such as PEDOT, which is very polar and dissolves only in hydrogen-bonding solvents like water, and (ii) a light emitting polymer coating that is non-polar, which dissolves only in non-polar solvents such as toluene or xylene. In order to remove multiple polymer coatings having extremely divergent solubility characteristics in a single wipe, suitable solvents for each polymer are dispersed in a third solvent to produce a homogeneous solution. The third, or dispersing, solvent is selected from a number of solvents, such as, but not limited to, alcohols (such as isopropanol, ethanol, methanol, and the like), ketones (such as acetone, methyl ethyl ketone, and the like), acetates, ethers, methylene chloride, or any solvent having intermediate solubility parameters. The solvent ratings for a typical light-emitting plastic and PEDOT are listed in Table 1.

TABLE 1
Solvent rating for polymers (1 = low solubility or insoluble;
5 = high solubility).

| Solvent | Light-emitting plastic | PEDOT |
|---|---|---|
| Water | 1 | 5 |
| Methanol | 2 | 2 |
| Ethanol | 3 | 1 |
| Isopropanol | 3 | 1 |
| Acetone | 1 | 1 |
| Toluene | 5 | 1 |
| Xylene | 5 | 1 |

### EXAMPLE 2

### Removal of Coating Comprising Polymers Having Similar Solubility Characteristics (i.e., with Intermediate Solubility Parameters).

Good solvents include either one-component systems having solubility parameters that closely match the solubility parameters of the polymer film (or films), or multi-component solvent systems having effective solubility parameters that match the solubility parameters of the polymer. The solvents in the multi-component system do not necessarily have to be a good solvent for the polymer. For example, neither CCl₄ nor ethanol are good individual solvents for polymethylmethacrylate (PMMA), but a binary mixture of CCl₄ and ethanol is a good solvent for PMMA because the effective solubility parameter of the mixture matches that of PMMA.

### EXAMPLE 3

### Wiping Example—Selective Removal of Top Coating without Damaging Underlying Layer

In this example, a PEDOT layer is spin coated onto an indium tin oxide (ITO) coated glass substrate and baked at 200° C. for 1 hour. A layer of light emitting plastic (i.e., electro-luminescent layer) is then spin-coated on top of the PEDOT layer. The patterned area is wiped by solvent assisted wiping (SAW) in which xylene was the only solvent used to remove portions of the electro-luminescent layer.

### EXAMPLE 4

### Wiping Example—Simultaneous Removal of Both Coating Layers

The PEDOT layer is spin coated onto an indium tin oxide (ITO) coated glass substrate and baked at 200° C. for 1 hour. A layer of light emitting plastic (or electro-luminescent layer) is spin-coated on top of the PEDOT layer. The patterned area is wiped by solvent assisted wiping (SAW) with a solvent mixture consisting of water, isopropanol, and xylene so as to remove both PEDOT and electro-luminescent layers.

Wiping head 230 comprises at least one of a sponge, an elastomer, a thermoplastic, a thermoset, a fiber mat, a porous material, polyurethane rubber, synthetic rubber, natural rubber, silicones, PDMS, textured materials, and combinations thereof. In one embodiment of the invention, wiping head 230 is a fixed head. In another embodiment, wiping head 230 is movable with respect to substrate 110. Alternatively, wiping head 230 and substrate 110 may be moved simultaneously with respect to each other. In still another embodiment, wiping head 230 is rotatable. In a further embodiment, wiping head 230 is a rotatable wheel.

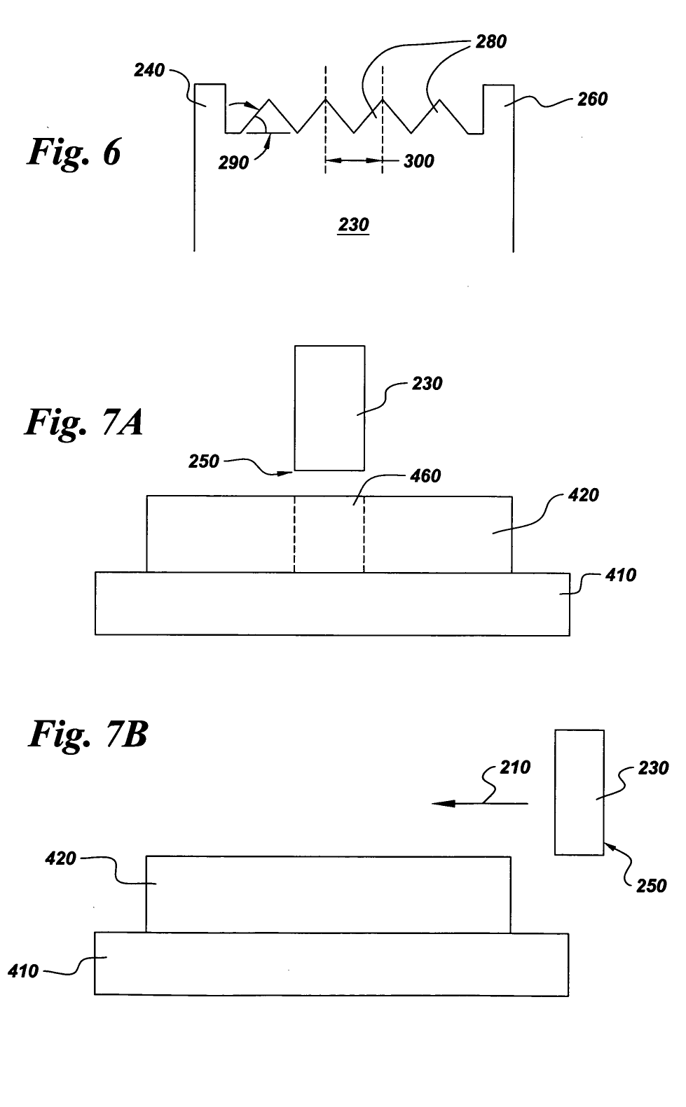

The step of tangentially contacting a portion 460 (FIG. 7B) of the at least one coating 420 with wiping head 230 comprises contacting a portion 460 of the at least one coating 420 in a tangential direction 210 with a contact surface of wiping head 230. A schematic cross-sectional view of the contact surface of wiping head 230 is shown in FIG. 6. In one embodiment, shown in FIG. 6, the contact surface 240 has a predetermined structure, or geometry. In one embodiment, the predetermined structure comprises at least one prism 280, with the at least one prism 280 having a predetermined angle 290. The at least one prism 280 has a geometric profile, such as a pointed profile or tip, a square profile, a trapezoidal profile, a rounded profile or tip, and the like. In another embodiment, the predetermined geometry comprises a plurality of prisms 280, wherein the plurality of prisms 280 are separated from each other by a predetermined pitch 300, as shown in FIG. 6. The plurality of prisms may include prisms having the same profile, or prisms having different profiles, arranged in either a random or predetermined regular order. In one embodiment, pitch 300 is about 50 microns. Wiping head 230 has a structure comprising a plurality of protrusions, such as, for example, plurality of prisms 280, to apply concentrated force to portion 460 so as to remove portion 460 and pattern the film. Wiping head protrusions are separated by indentations for carrying solvent to the film surface. The film surface is either moistened or premoistened by solvent in the liquid phase. In another embodiment, the film surface is moistened or premoistened by solvent in the vapor phase.

In one embodiment of the claimed method, the contact surface further includes at least one sidewall 260 disposed on at least one edge of the contact surface 240. In another embodiment, the method further includes the step of premoistening portion 460 (FIG. 7A) prior to wiping portion 460 with wiping head 230. The step of wiping the portion 460 with the wiping head to remove the portion 460 of the at least one coating 420 from the substrate 410 (FIG. 7A) comprises translating the substrate 410 in a predetermined direction with respect to wiping head 230. In another embodiment, wiping head 230 wipes the portion 460 in a direction parallel to the predetermined direction. In another embodiment, wiping head 230 wipes the portion 460 in a direction other than parallel to the predetermined direction. In another embodiment, the step of providing the substrate 410 comprises providing a continuous sheet of the substrate from a supply roll. In another embodiment the method further includes the step of collecting the continuous sheet on a take-up roll.

In another embodiment of the claimed invention, an apparatus is disclosed for selectively removing a portion 460 at least one coating 420 from a surface of a substrate 410. The apparatus comprises a means for supplying the substrate 410 having the at least one coating 420, a wiping head 230 for removing a portion 460 of the at least one coating 420, wherein the wiping head 230 contacts the at least one coating 420 in a tangential direction 210, and a means for collecting the substrate after removing the portion 460.

In another embodiment of the claimed invention, a wiping head 230 is disclosed for removing a portion 460 of at least one coating 420 disposed on a surface of a substrate 410. The wiping head 230 comprises a contact surface 240 for contacting and removing portion 460, wherein contact surface 240 contacts portion 460 in a tangential direction 210, and wherein contact surface 240 has a predetermined structure.

Although the examples described hereinabove are for an electroluminescent device, it is understood that the invention can be used in manufacturing features of other articles and devices, such as, but not limited to, microelectronic devices, photovoltaics, thin film transistors, electronic paper and displays, photonic devices, waveguides, microelectromechanical systems (MEMS), microfluidics devices, and the like.

While typical embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the present invention.

1. An electro-luminescent device, said electro-luminescent device comprising:
a) at least one electrode; and
b) an electro-luminescent layer disposed on said at least one electrode, wherein said electro-luminescent layer comprises an electro-luminescent polymeric material, and wherein said electro-luminescent layer has a first pattern disposed on a surface adjacent to said at least one electrode and has a substantially uniform thickness.

2. The electro-luminescent device according to claim 1, further comprising at least one conductive layer disposed between said at least one electrode and said electro-luminescent layer.

3. The electro-luminescent device according to claim 2, wherein said at least one conductive layer has a second pattern disposed on a surface adjacent to said first pattern.

4. The electro-luminescent device according to claim 3, wherein said first pattern is identical to said second pattern.

5. The electro-luminescent device according to claim 2, wherein said at least one conductive layer comprises at least one of poly (3,4-ethylenedioxythiophene), poly (3,4-propylenedioxythiophene), polystyrenesulfonate, polyvinylcarbazole, and combinations thereof.

6. The electro-luminescent device according to claim 1, wherein said electro-luminescent device is an organic light emitting diode.

7. The electro-luminescent device according to claim 1, wherein said at least one electrode comprises at least one of a metal, indium tin oxide, silicon, and combinations thereof.

8. The electro-luminescent device according to claim 1, wherein said first pattern comprises at least one coated portion, said at least one coated portion comprising an electro-luminescent material and having a coated surface area and at least one uncoated portion having an uncoated surface area, wherein said at least one uncoated portion intersects said coated portion to form a first coated area and a second coated area.

9. The electro-luminescent device according to claim 8, wherein said coated surface area is greater than said uncoated surface area.

10. The electro-luminescent device according to claim 8, wherein said at least one uncoated portion comprises at least one channel cut through said at least one coated portion, wherein said at least one channel has a channel width and a plurality of walls defining a boundary region, said boundary region having a boundary width.

11. The electro-luminescent device according to claim 10, wherein said boundary width is less than about 20% of said channel width.

12. The electro-luminescent device according to claim 8, wherein said coated portion has a thickness in a range from about 25 nm to about 150 nm.

13. The electro-luminescent device according to claim 1, wherein said electro-luminescent polymeric material comprises at least one of a polyfluorene, a polyphenylene, a poly para-(phenylenevinylene), and combinations thereof.

14. The electro-luminescent device according to claim 2, wherein said conductive layer comprises at least one of poly (3,4-ethylenedioxythiophene), and poly (3,4-propylenedioxythiophene), and combinations thereof.

15. The electro-luminescent device according to claim 1, wherein said at least one electrode is supported by a substrate, wherein said substrate comprises at least one of a polycarbonate, a polyolefin, a polyester, a polyimide, a polysulfone, an acrylate, glass, a metal foil, and combinations thereof.

16. An electro-luminescent layer for an electro-luminescent device, said electro-luminescent layer comprising an electro-luminescent polymeric material, wherein said layer is patterned and has a substantially uniform thickness, and wherein said electro-luminescent layer is formed by forming a continuous sheet of said electro-luminescent polymeric material and removing a portion of said continuous sheet by wiping a surface of said continuous sheet in a direction that is tangential to said surface.

17. The electro-luminescent layer according to claim 16, wherein said electro-luminescent layer is disposed adjacent to at least one conductive layer.

18. The electro-luminescent layer according to claim 16, wherein said pattern comprises at least one coated portion having a coated surface area and at least one uncoated portion having an uncoated surface area, wherein said at least one uncoated portion intersects said coated portion to form a first coated area and a second coated area.

19. The electro-luminescent layer according to claim 18, wherein said coated surface area is greater than said uncoated surface area.

20. The electro-luminescent layer according to claim 18, wherein said at least one uncoated portion comprises at least one channel cut through said at least one coated portion, wherein said at least one channel has a channel width and a plurality of walls defining a boundary region, said boundary region having a boundary width.

21. The electro-luminescent layer according to claim 20, wherein said boundary width is less than about 20% of said channel width.

22. The electro-luminescent layer according to claim 20, wherein said coated portion has a thickness in a range from about 50 nm to about 150 nm.

23. The electro-luminescent layer according to claim 16, wherein said electro-luminescent polymeric material comprises at least one of a conjugated polymer, polyfluorene, polyphenylene, poly para-(phenylenevinylene), and combinations thereof.

24. The electro-luminescent device according to claim 17, wherein said at least one conductive layer comprises at least one of poly (3,4-ethylenedioxythiophene), and poly (3,4-propylenedioxythiophene), and combinations thereof.

25. The electro-luminescent layer according to claim 16, wherein said continuous sheet is formed by applying a polymeric film to a substrate, patterning said polymeric film, baking said polymeric film at a predetermined temperature, coating the polymeric film with an electro-luminescent material to form said electro-luminescent layer, and patterning said electro-luminescent layer.

26. The electro-luminescent layer according to claim 16, wherein said portion of said continuous sheet is removed by wiping said surface of said continuous sheet with a wiping head.

27. The electro-luminescent layer according to claim 26, wherein said wiping head, comprises at least one of a sponge, an elastomer, a thermoplastic, a thermoset, a fiber mat, a porous material, polyurethane rubber, synthetic rubber, natural rubber, silicones, polydimethylsiloxane, textured materials, and combinations thereof.

28. An electro-luminescent device, said electro-luminescent device comprising:
a) at least one electrode;
b) an electro-luminescent layer, said electro-luminescent layer comprising an electro-luminescent polymeric material, wherein said layer is patterned and has a substantially uniform thickness, and wherein said electro-luminescent layer is formed by forming a continuous sheet of said electro-luminescent polymeric material and removing a portion of said continuous sheet by wiping a surface of said continuous sheet in a direction that is tangential to said surface; and
c) at least one conductive layer disposed between said at least one electrode and said electro-luminescent layer.

29. The electro-luminescent device according to claim 28, wherein said at least one conductive layer has a second pattern disposed on a surface adjacent to said first pattern.

30. The electro-luminescent device according to claim 29, wherein said first pattern is identical to said second pattern.

31. The electro-luminescent device according to claim 28, wherein said electro-luminescent device is an organic light emitting diode.

32. The electro-luminescent device according to claim 28, wherein said at least one electrode comprises at least one of a metal, indium tin oxide, silicon, and combinations thereof.

33. The electro-luminescent device according to claim 28, wherein said at least one conductive layer comprises at least one of poly (3,4-ethylenedioxythiophene), poly (3,4-propylenedioxythiophene), polystyrenesulfonate, polyvinylcarbazole, and combinations thereof.

34. The electro-luminescent device according to claim 28, wherein said first pattern comprises at least one coated portion having a coated surface area and at least one uncoated portion having an uncoated surface area, wherein said at least one uncoated portion intersects said coated portion to form a first coated area and a second coated area.

35. The electro-luminescent device according to claim 34, wherein said coated surface area is greater than said uncoated surface area.

36. The electro-luminescent device according to claim 34, wherein said at least one uncoated portion comprises at least one channel cut through said at least one coated portion, wherein said at least one channel has a channel width and a plurality of walls defining a boundary region, said boundary region having a boundary width.

37. The electro-luminescent device according to claim 36, wherein said boundary width is less than about 20% of said channel width.

38. The electro-luminescent device according to claim 34, wherein said coated portion has a thickness in a range from about 50 nm to about 150 nm.

39. The electro-luminescent device according to claim 28, wherein said electro-luminescent polymeric material comprises at least one of a conjugated polymer, polyfluorene, polyphenylene, poly para-(phenylenevinylene), and combinations thereof.

40. The electro-luminescent device according to claim 29, wherein said at least one conductive layer comprises at least one of poly (3,4-ethylenedioxythiophene), and poly (3,4-propylenedioxythiophene), and combinations thereof.

41. The electro-luminescent device according to claim 28, wherein said continuous sheet is formed by applying a polymeric film to a substrate, patterning said polymeric film, baking said polymeric film at a predetermined temperature, coating the polymeric film with an electro-luminescent material to form said electro-luminescent layer, and patterning said electro-luminescent layer.

42. The electro-luminescent device according to claim 28, wherein said portion of said continuous sheet is removed by wiping said surface of said continuous sheet with a wiping head.

43. The electro-luminescent device according to claim 42, wherein said wiping head comprises at least one of a sponge, an elastomer, a thermoplastic, a thermoset, a fiber mat, a porous material, polyurethane rubber, synthetic rubber, natural rubber, silicones, polydimethylsiloxane, textured materials, and combinations thereof.

44. A light source, said light source comprising a plurality of electro-luminescent devices, wherein each of said electro-luminescent devices comprises:
a) at least one electrode;
b) an electro-luminescent layer, said electro-luminescent layer comprising an electro-luminescent polymeric material, wherein said layer is patterned and has a substantially uniform thickness, and wherein said electro-luminescent layer is formed by forming a continuous sheet of said electro-luminescent polymeric material and removing a portion of said continuous sheet by wiping a surface of said continuous sheet in a direction that is tangential to said surface at least one conductive layer disposed between said at least one electrode and said electro-luminescent layer; and
c) at least one conductive layer disposed between said at least one electrode and said electro-luminescent layer.

45. The light source according to claim 44, wherein said at least one conductive layer has a second pattern disposed on a surface adjacent to said first pattern.

46. The light source according to claim 44, wherein said first pattern is identical to said second pattern.

47. The light source according to claim 44, wherein said electro-luminescent device is an organic light emitting diode.

48. The light source according to claim 43, wherein said at least one electrode comprises at least one of a metal, indium tin oxide, silicon, and combinations thereof.

49. The light source according to claim 44, wherein said at least one conductive layer comprises at least one of poly (3,4-ethylenedioxythiophene), poly (3,4-propylenedioxythiophene), polystyrenesulfonate, polyvinylcarbazole, and combinations thereof.

50. The light source according to claim 44, wherein said first pattern comprises at least one coated portion having a coated surface area and at least one uncoated portion having an uncoated surface area, wherein said at least one uncoated portion intersects said coated portion to form a first coated area and a second coated area.

51. The light source according to claim 50, wherein said coated surface area is greater than said uncoated surface area.

52. The light source according to claim 50, wherein said at least one uncoated portion comprises at least one channel cut through said at least one coated portion, wherein said at least one channel has a channel width and a plurality of walls defining a boundary region, said boundary region having a boundary width.

53. The light source according to claim 52, wherein said boundary width is less than about 20% of said channel width.

54. The light source according to claim 50, wherein said coated portion has a thickness in a range from about 50 nm to about 150 nm.

55. The light source according to claim 44, wherein said electro-luminescent polymeric material comprises at least one of a conjugated polymer, polyfluorene, polyphenylene, poly para-(phenylenevinylene), and combinations thereof.

56. The light source according to claim 44, wherein said at least one conductive layer comprises at least one of poly (3,4-ethylenedioxythiophene), and poly (3,4-propylenedioxythiophene), and combinations thereof.

57. The light source according to claim 44, wherein said continuous sheet is formed by applying a polymeric film to a substrate, patterning said polymeric film, baking said polymeric film at a predetermined temperature, coating the polymeric film with an electro-luminescent material to form said electro-luminescent layer, and patterning said electro-luminescent layer.

58. The light source according to claim 52, wherein said portion of said continuous sheet is removed by wiping said surface of said continuous sheet with a wiping head.

59. The light source according to claim 68, wherein said wiping head comprises at least one of a sponge, an elastomer, a thermoplastic, a thermoset, a fiber mat, a porous material, polyurethane rubber, synthetic rubber, natural rubber, silicones, polydimethylsiloxane, textured materials, and combinations thereof.

60. The light source according to claim 44, wherein said electro-luminescent devices are identical to each other.

61. A method of selectively removing at least one coating from a surface of the substrate, the method comprising the steps of:
a) providing the substrate, the substrate having the at least one coating disposed on the surface;
b) contacting a portion of the at least one coating with a wiping head; and
c) wiping the portion with the wiping head in a direction that is tangential to the surface to remove the portion of the at least one coating from the substrate.

62. The method according to claim 61, wherein the at least one coating is a wet coating.

63. The method according to claim 61, wherein the at least one coating is a dry coating.

64. The method according to claim 61, wherein the at least one coating has been baked onto the surface of the substrate.

65. The method according to claim 61, wherein the wiping head is a dry wiping head.

66. The method according to claim 61, wherein the wiping head is moistened with a solvent.

67. The method according to claim 77, wherein the solvent is at least one of water, methanol, ethanol, isopropanol, acetone, toluene, xylene, and combinations thereof.

68. The method according to claim 61, wherein the wiping head is moistened by injecting the solvent into the head while the head wipes the portion of the at least one coating.

69. The method according to claim 61, wherein the wiping head comprises at least one of a sponge, an elastomer, a thermoplastic, a thermoset, a fiber mat, a porous material, polyurethane rubber, synthetic rubber, natural rubber, silicones, polydimethylsiloxane, a textured material, and combinations thereof.

70. The method according to claim 61, wherein the wiping head is a fixed head.

71. The method according to claim 61, wherein the wiping head is movable with respect to the substrate.

72. The method according to claim 61, wherein the wiping head is rotatable.

73. The method according to claim 83, wherein the wiping head is a rotatable wheel.

74. The method according to claim 61, wherein the step of tangentially contacting a portion of the at least one coating with a wiping head comprises tangentially contacting a portion of the at least one coating with a contact surface of the wiping head, wherein the contact surface has a predetermined structure.

75. The method according to claim 91 wherein the predetermined structure comprises a plurality of protrusions for applying concentrated force to the surface.

76. The method according to claim 74, wherein the predetermined structure comprises at least one prism, the at least one prism having a predetermined angle.

77. The method according to claim 76, wherein the predetermined angle is about 90°.

78. The method according to claim 76, wherein the predetermined structure comprises a plurality of prisms, wherein the plurality of prisms are separated from each other by a predetermined pitch.

79. The method according to 78, wherein the pitch is about 50 microns.

80. The method according to claim 76, wherein the at least one prism has a trapezoidal profile.

81. The method according to claim 76, wherein the at least one prism has a rounded tip.

82. The method according to claim 76, wherein the at least one prism has a pointed tip.

83. The method according to claim 74, wherein the contact surface further includes at least one sidewall disposed on at least one edge of the contact surface.

84. The method according to claim 61, further including the step of premoistening the portion prior to wiping the portion with the wiping head.

85. The method according to claim 84, further including the step of premoistening the portion with a vapor solvent.

86. The method according to claim 84, further including the step of premoistening the portion with a liquid solvent.

87. The method according to claim 84, further including the step of premoistening a selected area of the coating.

88. The method according to claim 84, further including the step of premoistening the complete area of the coating.

89. The method according to claim 61, wherein the step of wiping the portion with the wiping head to remove the portion of the at least one coating from the substrate comprises translating the substrate in a predetermined direction with respect to the wiping head.

90. The method according to claim 89, wherein the wiping head wipes the portion in a direction parallel to the predetermined direction.

91. The method according to claim 89, wherein the wiping head wipes the portion in a direction other than parallel to the predetermined direction.

92. The method according to claim 61, wherein the step of providing the substrate comprises providing a continuous sheet of the substrate.

93. The method according to claim 92, wherein the step of providing a continuous sheet of the substrate comprises providing a continuous sheet of the substrate from a supply roll.

94. The method according to claim 92, further including the step of collecting the continuous sheet on a take-up roll.

95. The method according to claim 61, wherein the step of wiping the portion with the wiping head further comprises a continuous wiping.

96. The method according to claim 61, wherein the step of wiping the portion with the wiping head further comprises an intermittent wiping.

97. The method according to claim 61, wherein the substrate comprises at least one of a microelectronic device, a photovoltaic cell, a thin film transistor, electronic paper, electronic display, a photonic device, a waveguide, a microelectromechanical system (MEMS), and a microfluidic device.

98. An apparatus for selectively removing at least one coating from a surface of a substrate, the apparatus comprising:
a) a means for supplying the substrate having the at least one coating;
b) a wiping head for removing a portion of the at least one coating, wherein the wiping head tangentially contacts the at least one coating; and
c) a means for collecting the substrate after removing the portion.

99. The apparatus according to claim 98, wherein the means for supplying the substrate comprises a means for supplying a continuous sheet of the substrate.

100. The apparatus according to claim 99, wherein the means for supplying a continuous sheet of the substrate comprises a means for supplying the continuous sheet in rolled form.

101. The apparatus according to claim 100, wherein the means for collecting the substrate comprises a means for taking up the continuous sheet in rolled form.

102. The apparatus according to claim 98, wherein the wiping head is a dry wiping head.

103. The apparatus according to claim 98, wherein the wiping head is moistened with a solvent.

104. The apparatus according to claim 103, wherein the solvent is one of water, methanol, ethanol, isopropanol, acetone, toluene, xylene, and combinations thereof.

105. The apparatus according to claim 98, wherein the wiping head is moistened by injecting the solvent into the head while the head wipes the portion of the at least one coating.

106. The apparatus according to claim 98, wherein the wiping head comprises at least one of a sponge, an elastomer, a thermoplastic, a thermoset, a fiber mat, a porous material, polyurethane rubber, synthetic rubber, natural rubber, silicones, polydimethylsiloxane, textured materials, and combinations thereof.

107. The apparatus according to claim 98, wherein the wiping head is a fixed head.

108. The apparatus according to claim 98, wherein the wiping head is movable with respect to the substrate.

109. The apparatus according to claim 98, wherein the wiping head is rotatable.

110. The apparatus according to claim 109, wherein the wiping head is a rotatable wheel.

111. The apparatus according to claim 98, wherein the wiping head tangentially contacts a portion of the at least one coating with a contact surface of the wiping head, wherein the contact surface has a predetermined geometry.

112. The apparatus according to claim 111, wherein the predetermined structure comprises at least one prism, the at least one prism having a predetermined angle.

113. The apparatus according to claim 112, wherein the predetermined angle is about 90°.

114. The apparatus according to claim 112, wherein the predetermined structure comprises a plurality of prisms, wherein the plurality of prisms are separated from each other by a predetermined pitch.

115. The apparatus according to claim 114, wherein the pitch is about 50 microns.

116. The apparatus according to claim 112, wherein the at least one prism has a trapezoidal profile.

117. The apparatus according to claim 112, wherein the contact surface further includes at least one sidewall disposed on at least one edge of the contact surface.

118. The apparatus according to claim 98, further including a means for premoistening the portion prior to wiping the portion with the wiping head.

119. The apparatus according to claim 118, wherein the means for premoistening comprises a nozzle that directs one of a premoistening liquid and a premoistening vapor onto the portion prior to contact of the portion by the wiping head.

120. The apparatus according to claim 98, wherein the means for supplying the substrate supplies the substrate by translating the substrate in a predetermined direction with respect to the wiping head.

121. The apparatus according to claim 120, wherein the wiping head wipes the portion in a direction parallel to the predetermined direction.

122. The apparatus according to claim 120, wherein the wiping head wipes the portion in direction other than parallel to the predetermined direction.

123. A wiping head for removing a portion of at least one coating disposed on a surface of a substrate, the wiping head comprising a contact surface for contacting and removing the portion, wherein the contact surface tangentially contacts the portion, wherein the contact surface has a predetermined structure.

124. The wiping head according to claim 123, wherein the predetermined structure comprises at least one prism, the at least one prism having a predetermined angle.

125. The wiping head according to claim 124, wherein the predetermined angle is about 90°.

126. The wiping head according to claim 124, wherein the predetermined structure comprises a plurality of prisms, wherein the plurality of prisms are separated from each other by a predetermined pitch.

127. The wiping head according to claim 126, wherein the pitch is about 50 microns.

128. The wiping head according to claim 124, wherein the at least one prism has a trapezoidal profile.

129. The wiping head according to claim 123, wherein the contact surface further includes at least one sidewall disposed on at least one edge of the contact surface.

130. The wiping head according to claim 123, wherein the wiping head is fixed.

131. The wiping head according to claim 123, wherein the wiping head is rotatable.
